(19) United States
(12) Patent Application Publication
(10) Pub. No.: US 2007/0243684 A1
(43) Pub. Date: Oct. 18, 2007

(54) SEMICONDUCTOR DEVICE AND METHOD OF MANUFATURING THE SAME

(75) Inventors: Nobuyuki KATSUKI, Kanagawa (JP); Atsushi OGA, Kanagawa (JP); Shuuichi SENOU, Kanagawa (JP); Noriyuki OTA, Kanagawa (JP); Masahiro YOSHIDA, Kanagawa (JP); Kenta ARAI, Kanagawa (JP); Atsushi NAKAGAWA, Kanagawa (JP); Tomotaka MURAKAMI, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kawasaki (JP)

(21) Appl. No.: 11/767,074

(22) Filed: Jun. 22, 2007

Related U.S. Application Data
(62) Division of application No. 10/969,349, filed on Oct. 21, 2004.

(30) Foreign Application Priority Data
Oct. 23, 2003 (JP) 2003-362702

(51) Int. Cl. H01L 21/8234

(52) U.S. Cl. 438/276; 257/E21.618

(57) ABSTRACT

The semiconductor device includes a reference voltage generator circuit and a circuit different from the reference voltage generator circuit. A semiconductor element of the reference voltage generator circuit has a channel region where a substrate impurity concentration is substantially uniform at least in the vicinity of a drain region. A semiconductor element of the circuit different from the reference voltage generator circuit has a channel region where a substrate impurity concentration is higher than in other part of the region at least in the drain region.

### BACKGROUND OF THE INVENTION

1. Field of the Invention

The present invention relates to a semiconductor device and a method of manufacturing the same.

2. Description of Related Art

Higher density and higher speed are required for semiconductor integrated circuit devices, which are referred to hereinafter simply as the semiconductor devices, to improve performance. To meet these requirements, miniaturization of component devices is necessary. Thus, microfabrication technology has been developed and various structures and manufacturing methods for achieving high-speed operation of devices have been studied.

Metal Oxide Semiconductor Field Effect Transistors (MOSFET or MOS transistor) are miniaturized usually by reducing a gate length As the miniaturization of the MOSFET proceeds, however, the effect of a drain electric field on an electric field of a channel region becomes unignorable. This causes a short-channel effect, which is abrupt change in a threshold voltage with respect to the gate length. The short-channel effect leads to variation in the threshold value of supermicro MOSFET, which significantly decreases the margin in the circuit design. It is therefore critical for the future development of devices to suppress the short-channel effect due to miniaturization of devices.

One cause of the short-channel effect is an extending depletion layer from a drain region A Punchthrough Stopper structure such as a pocket structure and a halo structure is known as a structure of semiconductor devices which can suppress the short-channel effect, as described in Japanese Unexamined Patent Application Publication No. 2001-7331, and Takeshi Hori, “A 0.1-μm CMOS Technology with Tilt-Implanted Punchthrough Stopper (TIPS)”, IEDM (IEEE International Electron Devices Meeting), 1994, pp. 75-58. The pocket structure is such that a pocket region is formed in the boundary between a source region and a channel region, and the boundary between a drain region and the channel region. The pocket region is the same conductivity type as the channel region and a higher-impurity concentration than the channel region.

The semiconductor device having the pocket structure can prevent the depletion layer from protruding from the drain region, thereby suppressing the short-channel effect.

The semiconductor device having the pocket structure has the advantage of increasing a barrier height for carrier in the boundary between the source region and the channel region, and the boundary between the drain region and the channel region. However, it has the disadvantage of decreasing the current drive capacity of a MOS transistor.

The pocket structure increases the barrier height by increasing the impurity concentration of the pocket region in the channel region; as a result, the current drive capacity of the MOS transistor decreases, which causes a slower operation speed.

Specifically, if the impurity concentration of the channel region is uniform, a change in a drain voltage does not cause a change in a drain current. However, if the impurity concentration of the channel region is not uniform due to the presence of the pocket region and so on, the drain current is changed by a change in the drain voltage. Thus, if the MOS transistor having the pocket structure is used in a reference voltage generator circuit (see Japanese Unexamined Patent Application Publication No. 2001-172353, for example), a change in an input power supply voltage affects an output reference voltage.

If the impurity concentration of the channel region is not uniform, a drain current has drain voltage dependence even in a saturation region. This is disclosed in Bin Yu, Ed Nowak, and Kenji Noda, “REVERSE SHORT-CHANNEL EFFECTS & CHANNEL-ENGINEERING IN DEEP—SUBMICRON MOSFET'S: MODELING AND OPTIMIZATION”, Symposium on VLSI Technology Digest of Technical Papers, 1996, pp. 162-163.

It has now been discovered that, conventional semiconductor devices having a structure for suppressing the short-channel effect has a channel region with a nonuniform impurity concentration, and it is thus unable to output a constant voltage or current in a constant current source circuit such as a reference voltage generator circuit.

### SUMMARY OF THE INVENTION

According to one aspect of the present invention, there is provided a semiconductor device which includes a first circuit outputting a constant current or voltage regardless of a change in input current or voltage and a second circuit different from the first circuit. The first circuit is composed of a semiconductor element which includes a first gate electrode formed above a semiconductor substrate, a first channel region formed below the first gate electrode in the semiconductor substrate, a first source region formed in one side of the first channel region, and a first drain region formed in another side of the first channel region. The first channel region has a substantially uniform substrate impurity concentration at least in a vicinity of the first drain region. The second circuit is composed of a semiconductor element which includes a second gate electrode formed above the semiconductor substrate, a second channel region formed below the second gate electrode in the semiconductor substrate, a second source region formed in one side of the second channel region, and a second drain region formed in another side of the second channel region. The second channel region has a higher substrate impurity concentration in a vicinity of to the second drain region.

In this structures since the impurity concentration of the channel region of the first circuit is uniform, it is possible to output a stable and constant voltage or current from the first circuit, which is, for example, a reference voltage generator circuit or a constant current circuit. Further, since the impurity concentration of the channel region of the second circuit is not uniform, it is possible to suppress a short-channel effect in the second circuit.

According to another aspect of the present invention, there is provided a semiconductor device which includes a first circuit outputting a constant current or voltage regardless of a change in input current or voltage and a second circuit different from the first circuit. The first circuit is composed of a semiconductor element which includes a first gate electrode formed above a semiconductor substrate, a first channel region formed below the first gate electrode in the semiconductor substrate, a first source region formed in one side of the first channel region, and a first drain region formed in another side of the first channel region. The first channel region does not have a short-channel effect suppression structure. The second circuit is composed of a semiconductor element which includes a second gate electrode formed above the semiconductor substrate, a second channel region formed below the second gate electrode in the semiconductor substrate, a second source region formed in one side of the second channel region, and a second drain region formed in another side of the second channel region. The second channel region has a short-channel effect suppression structure.

In this structure, since the channel region of the first circuit does not have a short-channel suppression structure, it is possible to output a stable and constant voltage or current from the first circuit, which is, for example, a reference voltage generator circuit or a constant current circuit. Further, since the channel region of the second circuit has a short-channel suppression structure, it is possible to suppress a short-channel effect in the second circuit.

According to still another aspect of the present invention, there is provided a method of manufacturing a semiconductor device including a first semiconductor element for outputting a constant current or voltage and a second semiconductor element different from the first semiconductor element. The method includes forming a first gate electrode of the first semiconductor element in a first region above a semiconductor substrate, forming a second gate electrode of the second semiconductor element in a second region above the semiconductor substrate, forming a mask in the first region, forming a high concentration impurity region in a part of the semiconductor substrate below the second gate electrode; and forming a source region and a drain region corresponding to each of the first gate electrode and the second gate electrode.

This method allows manufacturing a semiconductor device capable of outputting a stable and constant voltage or current from a circuit having the first semiconductor element (for example, a reference voltage generator circuit or a constant current circuit) since the impurity concentration of the channel region of the first semiconductor element is uniform, and capable of suppressing a short-channel effect in a second semiconductor element since the impurity concentration of the channel region of the second semiconductor element is not uniform.

The present invention provides a semiconductor device and its manufacturing method which can output a constant and stable voltage or current while suppressing the short-channel effect.

### BRIEF DESCRIPTION OF THE DRAWINGS

The above and other objects, advantages and features of the present invention will be more apparent from the following description taken in conjunction with the accompanying drawings, in which:

FIG. 1 is a top view of a semiconductor device according to the present invention;

FIGS. 2A to 2C are block diagrams of a semiconductor element of a reference voltage generator circuit in the semiconductor device according to the present invention;

FIGS. 3A to 3C are block diagrams of a semiconductor element of a circuit different from the reference voltage generator circuit in the semiconductor device according to the present invention;

FIG. 4 is a circuit diagram of the reference voltage generator circuit according to the present invention;

FIG. 5 is a flowchart showing a method of manufacturing a semiconductor device according to the present invention;

FIG. 6 is a graph showing a voltage regulation in the reference voltage generator circuit according to the present invention; and

FIG. 7 is a circuit diagram of a timer circuit according to the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

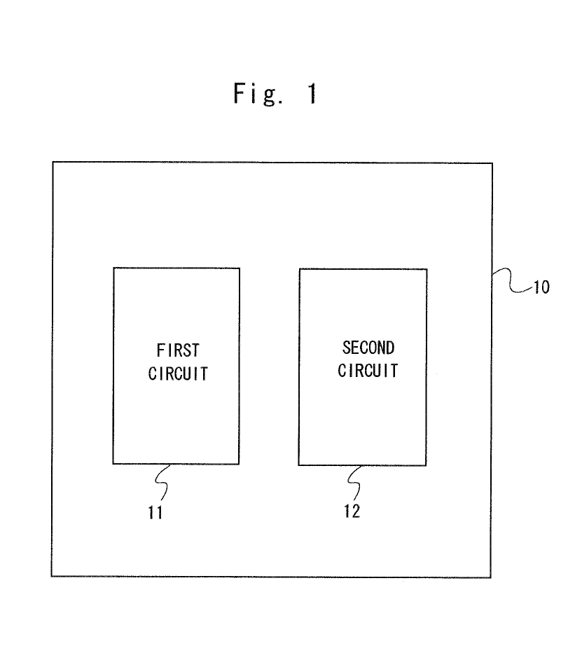

A semiconductor device and a method of manufacturing the same according to one embodiment of the invention are explained hereinafter with reference to FIGS. 1 to 7.

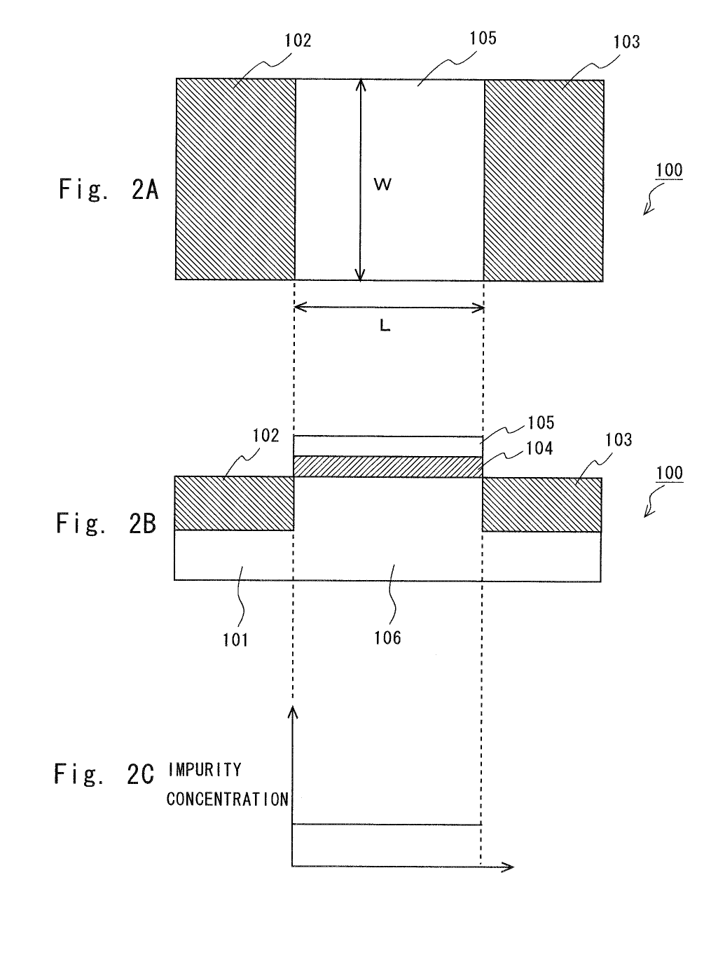

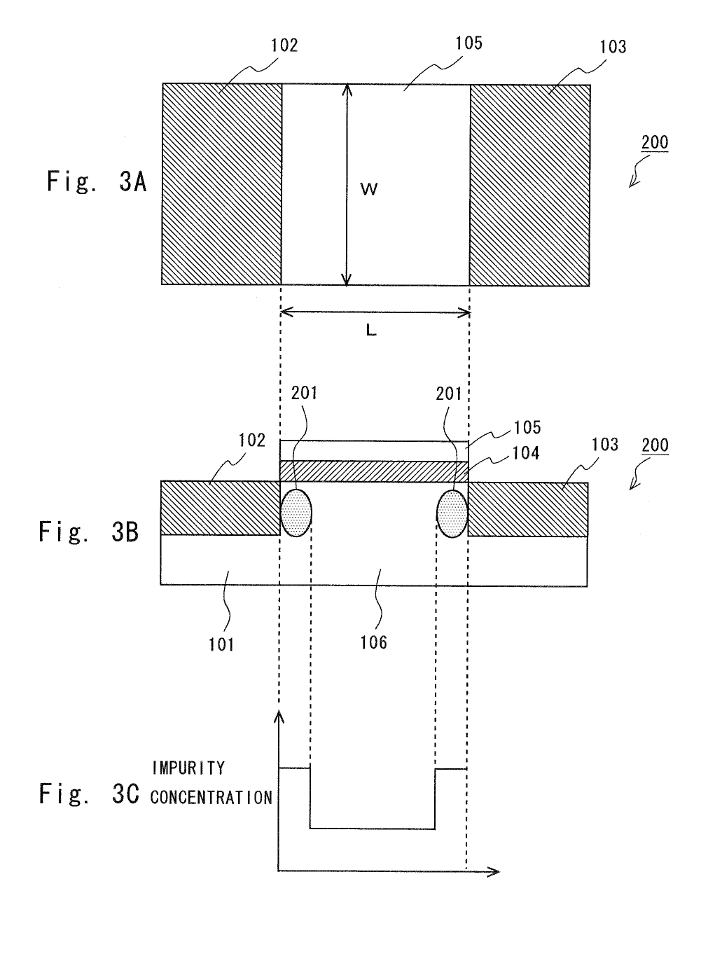

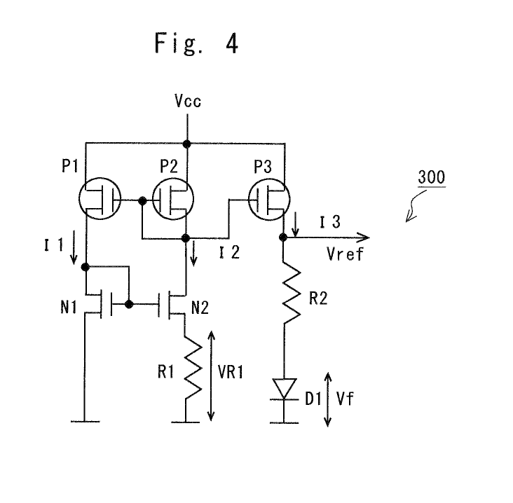

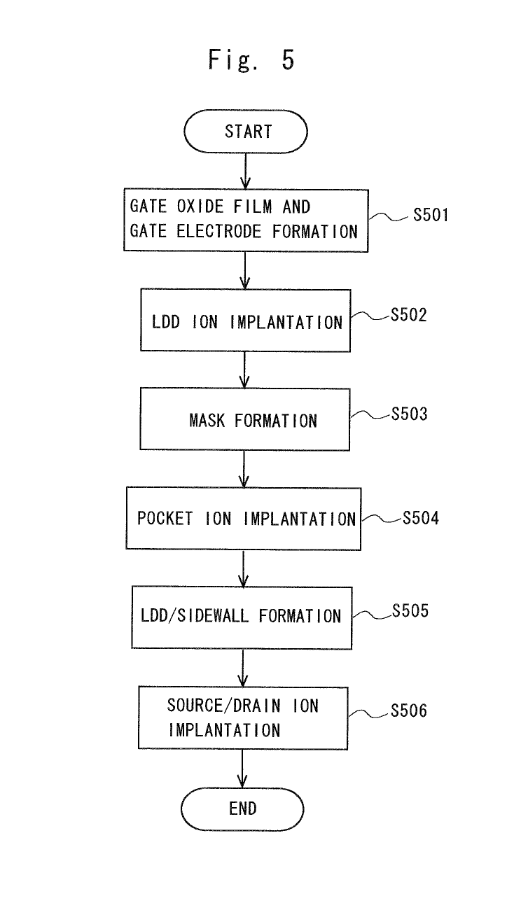

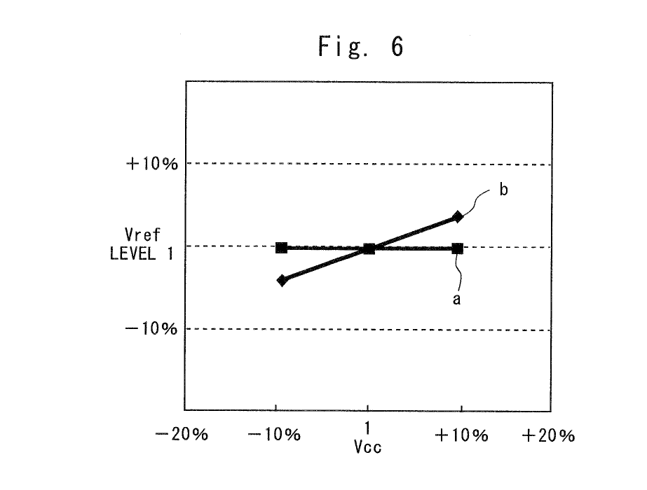

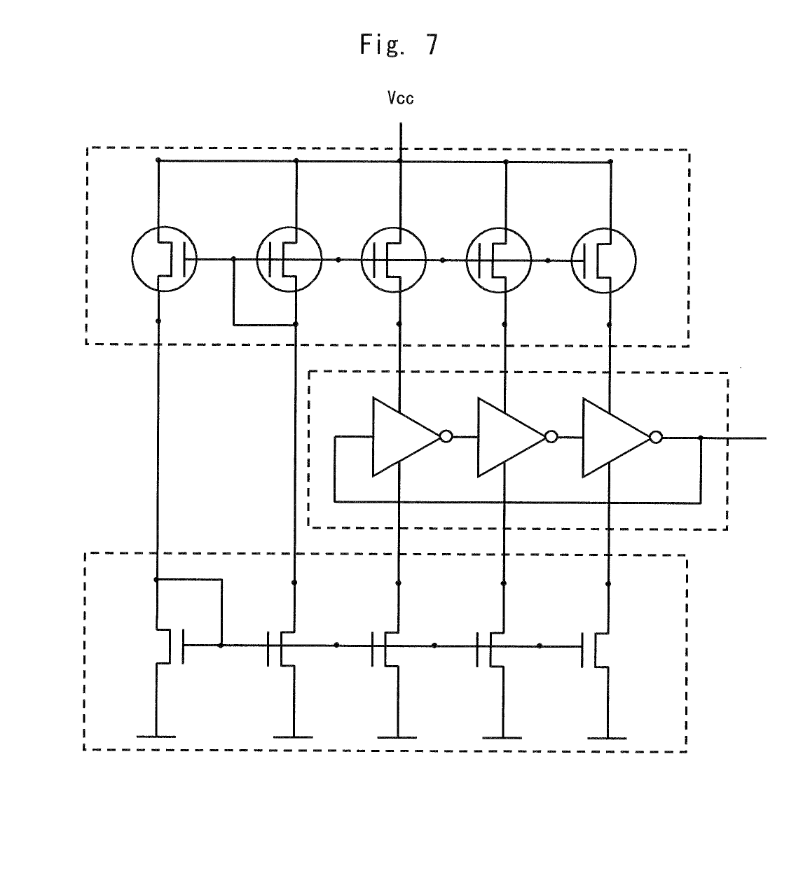

FIG. 1 is a top view of a semiconductor device of this embodiment. FIGS. 2A to 2C and FIGS. 3A to 3C are block diagrams of a semiconductor element used in the semiconductor device of this embodiment. FIG. 4 is a circuit diagram of a reference voltage generator circuit of this embodiment. FIG. 5 is a flowchart showing a method of manufacturing a semiconductor device of this embodiment. FIG. 6 is a graph showing an input voltage and output voltage regulation in the reference voltage generator circuit of this embodiment. FIG. 7 is a circuit diagram of a timer circuit of this embodiment.

The structure of the semiconductor device of this embodiment is explained below with reference to FIGS. 1 to 2C. As shown in FIG. 1, the semiconductor device 10 includes a first circuit 11 and a second circuit 12 which is different from the first circuit 11. The semiconductor device 10 has a reference voltage generator circuit, which is shown in FIG. 4 and described later. In this embodiment, the first circuit 11 is the reference voltage generator circuit, and the second circuit 12 is a circuit different from the reference voltage generator circuit. A MOS transistor constituting the reference voltage generator circuit is a semiconductor element 100, and a MOS transistor constituting the circuit different from the reference voltage generator circuit is a semiconductor element 200.

FIG. 2A is atop view of the semiconductor element 100. FIG. 2B is a sectional view of the semiconductor element 100. FIG. 2C is a graph showing an impurity concentration of the semiconductor element 100 in a channel region 106. As shown in FIGS. 2A and 2B, the semiconductor element 100 is composed of a gate electrode 105 formed above a silicon substrate 101 with a gate insulating film 104 placed there between. Above the silicon substrate 101, one side of the gate electrode 105 is a source region 102, and the other side is a drain region 103. It is noted that FIGS. 2A and 2B show the semiconductor element 100 only schematically, and other elements may be formed if necessary, including a silicide electrode in the source region 102 and the drain region 103, a sidewall region in the sidewall of the gate electrode 105, and a lightly doped drain (LDD) region in the vicinity of the source region 102 and the drain region 103.

The area between the source region 102 and the drain region 103 is a channel region 106. In the channel region 106, the length in the direction from the source region 102 to the drain region 103 (the carrier flow direction) is a channel length L, and the length in the direction perpendicular to the channel length L (the cross direction to the carrier flow) is a channel width W.

The semiconductor element 100 may be a N-channel MOS (NMOS) transistor or a P-channel MOS (PMOS) transistor. If it is a NMOS transistor, the silicon substrate 101 is P-type, and the source region 102 and the drain region 103 are N-type. If, on the other hand, it is a PMOS transistor, the silicon substrate 101 is N-type and the source region 102 and the drain region 103 are P-type.

For example, a drain voltage is applied between the source region 102 and the drain region 103, and a gate voltage is applied between the gate electrode 105 and the source region 102. Application of a gate voltage higher than a certain level forms an inversion layer in the channel region 106, and a drain current starts flowing between the source region 102 and the drain region 103. The gate voltage which triggers the flow of the drain current is called a threshold voltage. Further, application of a drain voltage higher than a certain level makes a saturation region, where a drain current is almost constant regardless of a change in a drain voltage. This is because the increase in the drain voltage forms a larger depletion layer in the channel region 106, which causes the inversion layer in the vicinity of the drain region 103 to disappear.

As shown in FIG. 2C, the impurity concentration in the channel region 106 is almost uniform in the channel region 106. If the impurity concentration of the channel region 106 is partly higher in the vicinity of the drain, increase in the width of the depletion layer due to increase in the drain voltage is suppressed, which reduces the short-channel effect. However, the channel potential of the high concentration impurity region changes in the boundary between the high concentration impurity region and the low concentration impurity region in the center part of the channel region, as taught by Bin Yu, et al. The channel potential in the drain side changes by the drain voltage; as a result, the drain current changes even if the channel length L is long. Thus, even in the MOSFET having the gate length which is long enough to make the short-channel effect negligible, a change in the drain voltage in the saturation region operation causes a change in the drain current accordingly. On the other hand, since the semiconductor element 100 has a uniform impurity concentration in the channel region 106, the drain current is not dependent on the drain voltage. The dependence of the drain current on the drain voltage may be eliminated if the channel impurity concentration is uniform at least in the vicinity of the drain region 103, which is the region where the width of the depletion layer changes.

If the substrate impurity concentration is uniform and the channel length L is too short, the short-channel effect occurs. The channel length L of the semiconductor element 100 is therefore preferably a length that does not cause the short-channel effect, for example, 10 μm or above.

This structure allows suppressing the short-channel effect and maintaining a constant drain current in -the saturation region. This embodiment uses the semiconductor element 100 for a circuit to keep a constant current or voltage, which is, the first circuit 11, so that it can output a stable current or voltage.

FIG. 3A is a top view of the semiconductor element 200. FIG. 3B is a sectional view of the semiconductor element 200. FIG. 3C is a graph showing the impurity concentration of the semiconductor element 200 in the channel region. 106. As shown in FIGS. 3A and 3B, the semiconductor element 200 has a pocket region 201 in the channel region 106 in the vicinity of the source region 102 and the drain region 103, in addition to the elements of the semiconductor element 100 of FIGS. 2A to 2C.

The pocket region 201 has a higher impurity concentration than the channel region 106. Thus, the impurity concentration in the channel region 106 is high in the pocket region 201 as shown in FIG. 3C. As described above, if the impurity concentration is not uniform, the drain current is dependent on the drain voltage in the saturation region.

On the other hand, the presence of the pocket region 201 allows preventing the short-channel effect from occurring when the channel length L is short. Hence, the channel length L of the semiconductor element 200 can be one-tenth or one-hundredth the channel length L of the semiconductor element 100.

The pocket region 201 may have any structure as long as it can prevent the short-channel effect, including a halo structure or other Punchthrough Stopper structures.

This embodiment uses the semiconductor element 200 for a circuit which is different from the circuit to keep a constant current or voltage, which is, the second circuit 12, so as to miniaturize the semiconductor device while suppressing the short-channel effect.

Now, the reference voltage generator circuit 300 of this embodiment is explained with reference to FIG. 4. The reference voltage generator circuit 300 receives a power supply voltage Vcc and outputs a constant reference voltage Vref. For example, the reference voltage Vref does riot vary even if the power supply voltage Vcc varies by about 10%. The reference voltage generator circuit 300 includes PMOS transistors P1, P2, P3, NMOS transistors N1 N2, resistors R1, R2, and a diode D1, as shown in FIG. 4.

The PMOS transistors P1, P2, and P3 are constant current sources, and the power supply voltage Vcc is supplied to their sources. The gates of the PMOS transistors P1, P2, and P3 are commonly connected. The gate width W and gate length. L of the PMOS transistors P1, P2, and P3 are respectively the same. Since the PMOS transistors P1, P2, and P3 have the same gate voltage, gate width W1 and gate length L, currents I1, I2, and I3 from P1, P2, and P3 are the same.

Further, the drain of the PMOS transistor P1 is connected to the drain of the NMOS transistor N1, and the drain of the PMOS transistor P2 is connected to the drain of the NMOS transistor N2. The drain of the NMOS transistor N1 is connected to its gate, and the source of the NMOS transistor N1 is grounded. The source of the NMOS transistor N2 is connected to one end of the resistor R1, and the other end of the resistor R1 is grounded. The gates of the NMOS transistors N1 and N2 are commonly connected.

The ratio WP/LP of the gate width W and the gate length L of the PMOS transistors P1 and P2 is set sufficiently smaller than the ratio WN1/LN1 of the gate width W and the gate length L of the NMOS transistor N1 and the ratio WN2/LN2 of the gate width W and the gate length L of the NMOS transistor N2. Thus, the current I1 (=I2) is sufficiently small, and the NMOS transistors N1 and N2 operate in a weak inversion region. The current I2 is thereby determined by resistance of the resistor R1 and a voltage VR1 on the resistor R1 (I2=VR1/R1). The channel length L1 of the NMOS transistor N1 and the channel length L2 of the NMOS transistor N2 are the same, and the channel width W2 of the NMOS transistor N2 is set about six to ten times larger than the channel width W1 of the NMOS transistor N1.

The drain of the PMOS transistor P3 is connected to one end of the resistor R2. The other end of the resistor R2 is connected to one end of the diode D1, and the other end of the diode D1 is grounded. A voltage at the drain of the PMOS transistor P3 is output as a reference voltage Vref. The diode D1 may be eliminated if the reference voltage Vref is output constantly.

Without counting the diode D1, the reference voltage Vref is calculated from the current I3 and the resistance of the resistor R2 (Vref=I3*R2) Further, since the current I3 and the current I2 are the same value, the reference voltage Vref is determined by the ratio of the resistor R1 and the resistor R2 (Vref=(R2/R1)*VR1). Thus, the reference voltage Vref can be set to an arbitrary value by appropriately setting the ratio of the resistance values.

This embodiment uses the semiconductor element 100 for the PMOS transistors P1, P2, P3, and the NMOS transistors N1, N2, which affect the reference voltage Vref. The semiconductor element 200 may be used for the diode D1, which does not affect the reference voltage Vref. It is also possible to use a diode element or the semiconductor element 100 for the diode D1. Use of the semiconductor element 200 allows further miniaturization.

Use of the semiconductor element 100 makes the drain current in the saturation region constant, thereby allowing maintaining a constant reference voltage Vref regardless of a change in the power supply voltage Vcc. In addition, use of the semiconductor element 200 allows further miniaturization.

A method of manufacturing the semiconductor device according to this embodiment is explained hereinafter with reference to FIG. 5. FIG. 5 shows the manufacturing process in the case of forming the semiconductor element 100 and the semiconductor element 200 on the same substrate.

First of all, before S501, an element isolation region for isolating elements on the silicon substrate 101 is formed on the silicon substrate 101 by element isolation techniques such as local oxidation of silicon (LOCOS) and shallow trench isolation (STI). Then, according to need, a well region of a given conductivity type is formed in a given area. Further, ion corresponding to the type of MOS transistor, (P-channel or N-channel), such as boron (B) ion, is implanted into the silicon substrate 101 as a given accelerating energy and dose amount, thereby forming the channel region 106 of the semiconductor elements 100 and 200. The dose amount is preferably 1*10 cm⁻² to 5*10¹³cm⁻² for a uniform concentration of the channel region 106.

Then, a gate insulating film 104 and a gate electrode 105 of the semiconductor elements 100 and 200 are formed on the silicon substrate 101 (S501). This step forms the gate insulating film 104 of a given film thickness on the surface of the silicon substrate 101 by a thermal oxidation process, for example. It is possible to form the well region and the channel region 106 after forming the gate insulating film 104. After that, a polysilicon film of a given thickness doped with phosphorus is deposited all over the surface by a chemical vapor deposition (CVD) process, for example. Further, the polysilicon film is patterned by normal lithography and etching processes to form the gate electrode 105 with gate length L.

Then, LDD ion is implanted into the semiconductor elements 100 and 200 of the silicon substrate 101 (S502). This step implants the ion corresponding to the type of MOS transistor, such as arsenic (As) ion, as a given accelerating energy and dose amount, using the gate electrode 105 as a mask, for example, thereby forming a LDD region in the silicon substrate 101. Annealing is performed to activate the implanted impurity.

Then, a mask is formed in an area to be the semiconductor element 100 (S503). This step forms a masking oxide film, for example, and applies a resist. The mask is formed in order to save the area where the pocket region 201 is not formed. Thus, in the case of forming the pocket region in all the semiconductor element on one substrate, there is no need to form the mask.

Then, pocket ion is implanted into the channel region 106 of the semiconductor element 200 (S504). This step implants the ion corresponding to the type of MOS transistor, such as boron ion, into the surface of the silicon substrate 101 as a given accelerating energy and dose amount, thereby forming the pocket region 201. The dose amount is preferably at a higher concentration than the channel region 106. The ion may be implanted into the silicon substrate 101 vertically or obliquely.

Then, a LDD and a sidewall are formed in the side wall of the gate electrode 105 of the semiconductor elements 100 and 200 (S505). This step deposits a silicon oxide film all over the surface of the silicon substrate 101 by the CVD process, for example, and etches it back, thereby forming a sidewall region in the side wall of the gate electrode 105. Further, a LDD region is formed in the same way as S502 if needed.

Then, ion is implanted to form a source region 102 and a drain region 103 of the semiconductor elements 100 and 200 (S506). This step implants the ion corresponding to the type of MOS transistor, such as arsenic ion, as a given accelerating energy and dose amount, using the gate electrode 105 and the sidewall region as a mask, for example, thereby forming the source region 102 and the drain region 103. Annealing is performed to activate the implanted impurity.

After that, a silicide electrode is formed on the gate electrodes 105, in the source region 102, and in the drain region 103 of the semiconductor element 100 and 200, by a normal Salicide process, for example. In the case of forming a PMOS transistor and a NMOS transistor on one substrate, a mask is formed in each step according to need and processed in the same way.

The above steps allows forming the semiconductor element 100 where the channel region 106 has a uniform impurity concentration and the semiconductor element 200 where the channel region 106 includes the pocket region 201 having a higher impurity concentration on one substrate.

Though the above description explains the case where the semiconductor elements 100 and 200 are MOSFET, it is possible to replace the oxide film by another insulating film such as a high dielectric film like a HfO₂ film for the gate insulating film 104.

Now, the input voltage and output voltage regulation in the reference voltage generator circuit according to this embodiment is explained with reference to FIG. 6.

In FIG. 6, the horizontal axis shows the regulation of the power supply voltage Vcc of the reference voltage generator circuit 300, and the vertical axis shows the regulation of the reference voltage Vref, which is output of the circuit. The line “a” of the graph in FIG. 6 indicates the value of the reference voltage generator circuit including the semiconductor element 100 of this embodiment explained in FIG. 4, and the line “b” indicates the value of the reference voltage generator circuit including a semiconductor element having a conventional pocket structure.

The line “b” indicates that the reference voltage Vref changes as the power supply voltage Vcc changes. On the other hand, the line “a” indicates that the reference voltage Vref remains constant when the power supply voltage Vcc changes. Thus, use of the semiconductor element 100 of this embodiment allows the reference voltage Vref to be constant even if the power supply voltage Vcc varies by about 10%.

As described above, use of the semiconductor element 100 where the channel region 106 has a uniform impurity concentration for the reference voltage generator circuit, and use of the semiconductor element 200 where the channel region 106 includes the pocket region 201 having a higher impurity concentration for a circuit different from the reference voltage generator circuit in the semiconductor device allows obtaining a stable reference voltage output from the reference voltage generator circuit and suppressing the short-channel effect occurring by the miniaturization of the semiconductor device.

Though the above description explains the case of using the semiconductor element 100 for the reference voltage generator circuit, it is not restricted thereto, as long as the semiconductor element 100 is used for a part which affects output voltage or current, and the semiconductor element 200 is used for another part. The semiconductor element 100 may be applied also to a reference voltage generator circuit having another structure, a timer circuit, a constant current source circuit, a booster circuit or step-down circuit connected to a reference voltage generator circuit, and so on.

The semiconductor element 200 is applied to a circuit in which operating in a high-speed is more important than preventing a change of drain current by a change in drain voltage. For the high-speed operation, the channel length L of the MOS transistor is reduced, and a pocket region is formed to prevent the short-channel effect. Examples of such circuit include an inverter chain constituting an input/output buffer, and decoder.

FIG. 7 shows an example of a timer circuit in which the semiconductor element 100 is used. The timer circuit receives a power supply voltage Vcc and outputs a clock at a certain cycle. The timer circuit is composed of a plurality of PMOS transistors (shown at the upper part of FIG. 7), a plurality of NMOS transistors, (shown at the lower part of FIG. 7), and ring oscillator inverters (shown in the middle part of FIG. 7) The semiconductor element 100 is applied to the PMOS and NMOS transistors, and the semiconductor element 200 is applied to the ring oscillator inverters. Use of the semiconductor element 100 for the PMOS and NMOS transistors allows a current supplied from the constant current source to the ring oscillator to be constant regardless of the power supply voltage Vcc. Further, the clock cycle output from the ring oscillator is also constant, not dependent on the power supply voltage Vcc.

It is apparent that the present invention is not limited to the above embodiment, that may be modified and changed without departing from the scope and spirit of the invention.

1. A method of manufacturing a semiconductor: device including a first semiconductor element for outputting a constant current or voltage and a second semiconductor element different from the first semiconductor element, the method comprising:
forming a first gate electrode of the first semiconductor element in a first region above a semiconductor substrate;
forming a second gate electrode of the second semiconductor element in a second region above the semiconductor substrate;
forming a mask in the first region;
forming a high concentration impurity region in a part of the semiconductor substrate below the second gate electrode; and
forming a source region and a drain region corresponding to each of the first gate electrode and the second gate electrode.

2. The method of manufacturing a semiconductor device according to claim 1, wherein a part of the semiconductor substrate below the first gate electrode of the first semiconductor element has a substantially uniform substrate impurity concentration.

3. The method of manufacturing a semiconductor device according to claim 1, wherein a first channel length of the first semiconductor element is longer than a second channel length of the second semiconductor element.

4. The method of manufacturing a semiconductor device according to claim 1, wherein the first semiconductor element is an element of a constant current source circuit.

5. The method of manufacturing a semiconductor device according to claim 1, wherein the first semiconductor element is an element of a reference voltage generator circuit.

6. The method of manufacturing a semiconductor device according to claim 1, wherein the first semiconductor element is an element of a timer circuit.

7. The method of manufacturing a semiconductor device according to claim 1, wherein the second circuit is composed of a semiconductor element which is not a memory cell.

8. The method of manufacturing a semiconductor device according to claim 4, wherein the second circuit is composed of a semiconductor element which is not a memory cell.

9. The method of manufacturing a semiconductor device according to claim 5, wherein the second circuit is composed of a semiconductor element which is not a memory cell.

10. The method of manufacturing a semiconductor device according to claim 6, wherein the second circuit is composed of a semiconductor element which is not a memory cell.
